(19) United States
(12) Patent Application Publication
(10) Pub. No.: US 2006/0265632 A1
(43) Pub. Date: Nov. 23, 2006

(54) Chip capable of testing itself and testing method thereof

(75) Inventors: Jien-Chung Huang, Taipei (TW); Wei-Kuo Chia, Taipei (TW); Kae-Jiun Mo, Taipei (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: VIA TECHNOLOGIES INC.

(21) Appl. No.: 11/274,780

(22) Filed: Nov. 15, 2005

(30) Foreign Application Priority Data
May 18, 2005 (TW) 94116179

(51) Int. Cl. G01R 31/28

(52) U.S. Cl. 714/738

(57) ABSTRACT

A chip capable of testing itself and a testing method thereof. The chip capable of testing itself is electrically connected to a processor. The chip tests itself with a testing mode. The chip comprises a first circuit, a pattern generator, a circuit to be tested, and a result generator. The first circuit is electrically connected to the processor. The pattern generator generates a test pattern by way of pseudo-random. The circuit to be tested receives a command from the processor through the first circuit and executes the command according to the test pattern to output a testing result. The result generator generates a signature result according to the testing result. Subsequently, the chip is verified by the signature result.

This application claims the benefit of Taiwan application Ser. No. 94116179, filed May 18, 2005, the subject matter of which is incorporated herein by reference.

### BACKGROUND OF THE INVENTION

1. Field of the Invention

The invention relates in general to a testing chip and a testing method thereof, and more particularly to a chip capable of testing itself and a testing method thereof.

2. Description of the Related Art

The chip nowadays is superior to conventional circuit boards in many aspects, such as in weight, volume, function, and price. However, if the testing issue is ignored before designing a chip, problems, like testing prices higher than manufacturing prices, will show up when chips become mass products. Thus, testing is a significant issue when designing a chip.

Referring to FIG. 1, a block diagram of a conventional testing chip applied in a computer system is shown. The computer system 100 includes a processor 110, a chip 120 and a memory 130. When the chip 120 is in testing status, the processor 110 controls the chip 120 according to a control signal CO1. The chip 120 here is an integrated chip for example, including a North Bridge 121 and a graphic circuit 122. The input and output of the chip 120 are through the North Bridge 121, and the input and output of the graphic circuit 122 are through the North Bridge 121 as well. The graphic circuit 122 receives a test pattern P12 and a signal command CO1 respectively from the memory 130 and the processor 110 via the North Bridge 121. After processing, the graphic circuit 122 outputs a testing result P14 to memory 130 via the North Bridge 121.

Nevertheless, the frequency of the FSB (Front Side Bus) through which the processor 110 communicates with the chip 120 is 400 MHz or 800 MHz, the operating frequency of the memory 130 is 266 MHz or 333 MHz, and the working frequency of the graphic circuit 122 is 266 MHz or 333 MHz. In the cause of supporting multiple combinations of frequency, the testing process is more complicated and difficult to debug, at last leading to lower testing efficiency. To testers, the testing process is limited for those frequencies that do not allow to be changed.

In another aspect, a general test pattern can be recognized by human eyes, such as a pattern with coordinates in three points. When inputting the pattern, the graphic circuit performs an operation and outputs the result as a figure of triangle to verify chips. Yet, it is not easy to set up a test pattern and it delays testing time for producing mass data of testing result by the graphic circuit.

The chip 120 could be verified through ATE (Auto Test Equivalent) during testing. But the price of ATE, usually over $US 1,000,000 dollars, is excessively expensive. In addition, the complicated circuits on chips nowadays exceed the processing abilities of ATE in speed and storage. Thus, the testing result with lower fault coverage reduces the quality of products, increases testing time, and indirectly raises the cost.

To verify chips conveniently, the BIST (Built-in Self Test) technology of chips start to attract great attention. At present, SoC (System on Chip) is widely applied; thus large-sized chips count on BIST even more. However, BIST chips usually need to redesign the circuits, such as IEEE TRANSACTIONS ON COMPUTER-AIDED DESIGN ON INTEGRATED CIRCUIT AND SYSTEM.VOL.20.NO.4.APRIL 2001, the paper “Bit-Fixing in Pseudorandom Sequences for Scan BIST” by Touba et al., it increases the difficulty of research due to the circuits needs to be redesigned to correspond to the self test.

### SUMMARY OF THE INVENTION

The invention provides a chip capable of testing itself and a testing method thereof, which could simplify the verifying process, and reduces the testing time and time to markets.

The invention provides a chip capable of testing itself. The chip comprises a pattern generator for generating a test pattern, a circuit to be tested for receiving the test pattern and outputting a testing result according to the test pattern, and a result generator for generating a signature result according to the testing result and then verifying the chip by outputting the signature result.

The invention further provides a chip capable of testing itself. The chip tests itself with a testing mode and electrically coupled to a processor. The chip comprises a first circuit, a pattern generator, a circuit to be tested and a result generator. The first circuit is electrically connected with the processor. The pattern generator generates a test pattern by a pseudo-random technique. The circuit to be tested receives a command from the processor through the first circuit and executes the command to output a testing result. The result generator generates a signature result according to the testing result, and then verifies the chip according to the signature result.

The invention provides a self-testing method for a chip. The chip has a testing mode and is electrically connected with a processor. The self-testing method is executed under the testing mode, including following steps: First, a test pattern is generated by a pseudo-random technique. Then a command from the processor is executed according to the test pattern to generate a testing result. After that, a signature result is generated according to the testing result. At last, the chip is verified according to the signature result.

Other features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a block diagram of a conventional testing chip applied in computer system.

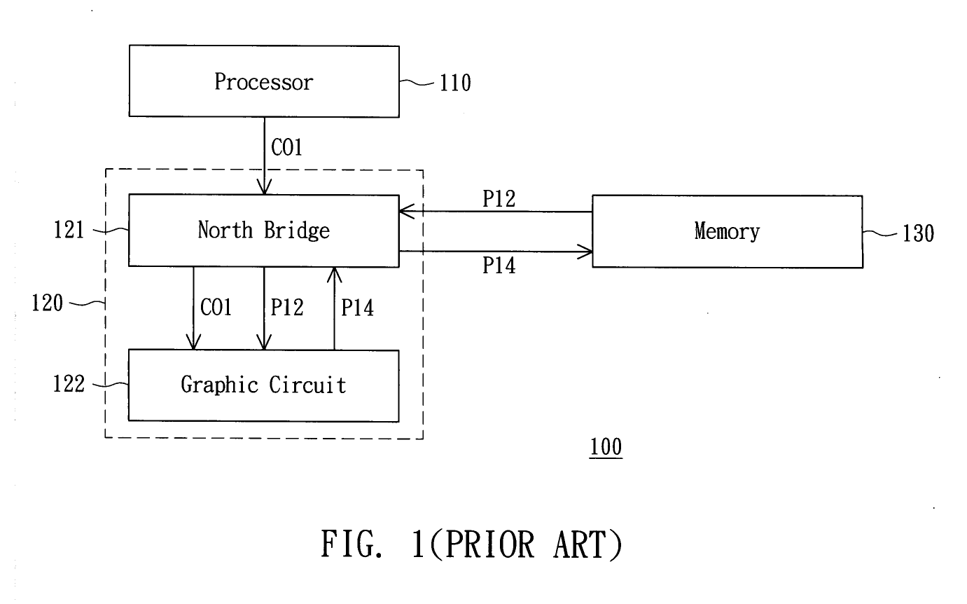

FIG. 2 is a block diagram of a testing chip according to the preferred embodiment of the invention.

FIG. 3 is a flowchart showing a method of testing self-testing chip according to the preferred embodiment of the invention.

FIG. 4 is a block diagram of an integrated chip according to another embodiment of the invention.

### DETAILED DESCRIPTION OF THE INVENTION

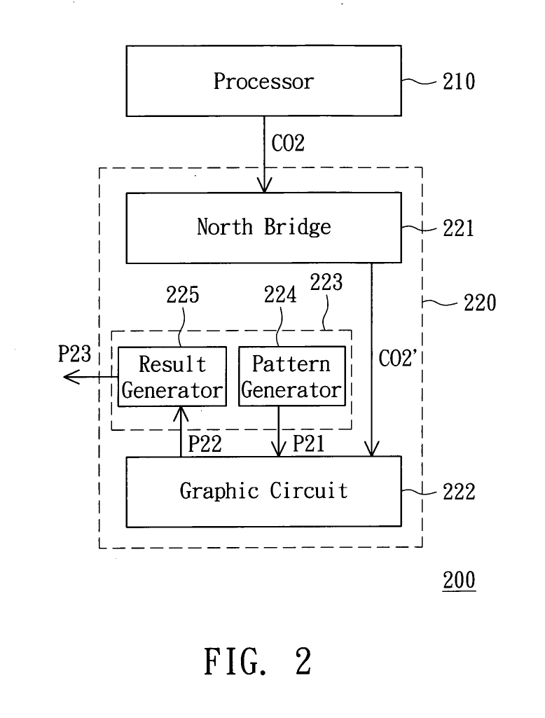

Referring to FIG. 2, a block diagram of an integrated chip applied in a computer system is shown according to a preferred embodiment of the invention. The computer system 200 includes an integrated chip 220 and a processor 210. The integrated chip 220 is electrically connected with the processor 210, which is a CPU (Center Process Unit) in the embodiment. The chip 220 tests itself according to a testing mode. The integrated chip 220 includes a North Bridge 221, a testing circuit 223 and a graphic circuit 222. The North Bridge 211 is electrically connected with the processor 210 and receives the command CO2 from the processor 210 to output a command CO2′ to the graphic circuit 222. The testing circuit 223 includes a pattern generator 224 and a result generator 225. The pattern generator 224 generates a test pattern P21 by a pseudo-random technique. The graphic circuit 222 receives the command CO2′ and executes the command CO2′ according to the test pattern P21 to output a testing result P22. The result generator 225 generates a signature result P23 according to the testing result P22, and at last verifies the chip 220 according to signature result P23.

The pattern generator 224 in the embodiment is a LFSR (Linear Feedback Shift Register). The result generator 225 in the embodiment is a MISR (Multiple-Input Signature Register). The result generator 225 generates the signature result P23 according to the testing result P22, and compresses data size for decreasing the data of signature result P23 so as to reduce testing time.

The ways to generate signature result P23 by the result generator 225 are as follows: one way is the result generator 225 generates the signature result P23 according to the testing result P22 by using a checksum algorithm. For example, the testing result P22 output by the graphic circuit 222 includes many sub-testing results. The result generator 225 generates many sub-signature results according to those sub-testing results and then sums these sub-signature results together to obtain the signature result P23. The other way is the result generator 225 generates the signature result P23 according to the testing result P22 by performing a polynomial operation.

In the embodiment, the chip to be tested 220 uses the BIST technology, thus no need to read the test pattern from a memory. Therefore, in a testing phase, the value of test pattern has no substantial meaning. What is required is to input numbers for the graphic circuit 222 to operate and to calculate the signature result P23 according to the testing result P22 to verify the chip 220 at last. The pattern generator 224 generates the test pattern P21 by a pseudo-random technique; thus the graphic circuit 222 executes under a testing status without being limited from the frequency of the memory so as to simplify the working environment. In addition, the method of a chip testing itself could match up the frequency of the chip so as to achieve an at-speed utility.

Though in the embodiment, the BIST is provided in the chip of North Bridge and the integrated graphic circuit, the method of LFSR generating the test pattern by a pseudo-random technique and the method of MISR generating the signature result are not limited in this embodiment. Any embodiment follows this concept should be in the scope of the invention.

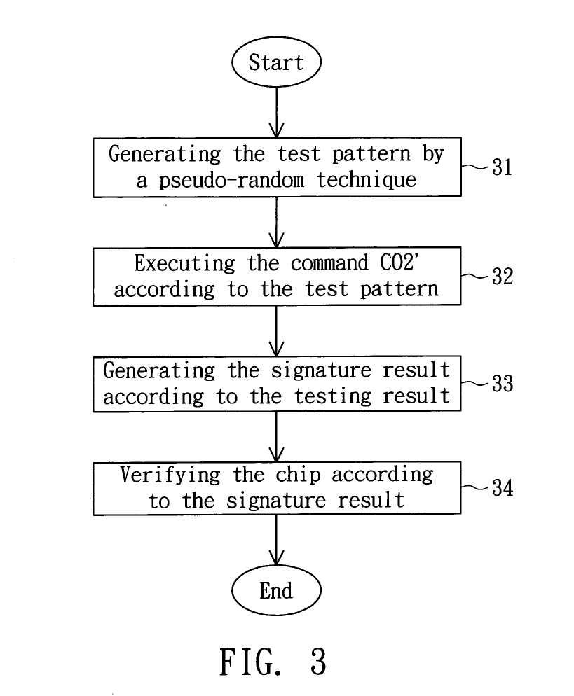

Referring to FIG. 3, a flowchart of testing a self-testing chip is shown according to the preferred embodiment of the invention. First, the test pattern P21 is generated by a pseudo-random technique, as shown in step 31. Then the command CO2′ is executed according to the test pattern P21 to output the testing result P22, as shown in step 32. After that, the signature result P23 is generated according to the testing result P22, as shown in step 33. At last, the chip 220 is verified according to signature result P23, as shown in step 34. The verifying method uses the signature result P23 and the result of simulation for comparison to ensure the accuracy of the operation of the graphic circuit 222.

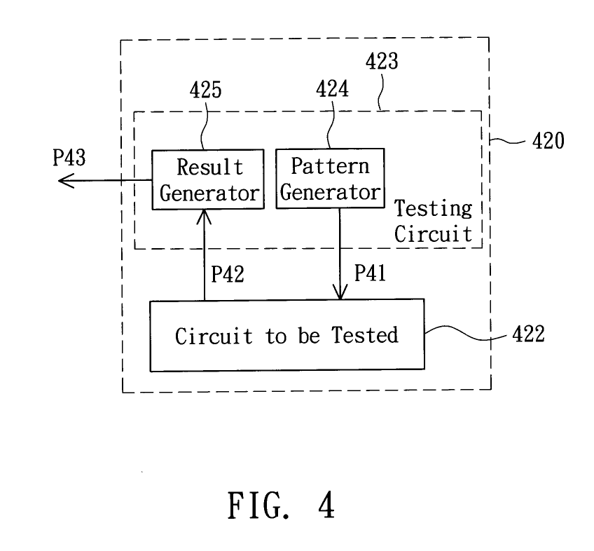

Referring to FIG. 4, a block diagram of an integrated chip is shown according to another embodiment of the invention. An integrated chip 420 tests itself under a testing mode. The integrated chip 420 includes a testing circuit 423 and a circuit to be tested 422. The circuit to be tested 422 could be a circuit provided to the physical layer of Internet, a circuit in charge of transmitting function of USB, or a bridge circuit. The testing circuit 423 includes a pattern generator 424 and a result generator 425. The pattern generator 424 generates a test pattern P41 by a pseudo-random technique. The circuit to be tested 422 receives and executes the test pattern P41 to output testing result P42. The result generator 425 generates a signature result P43 according to testing result P42, and at last verifies the chip 420 according to signature result P43.

The pattern generator 424 in the embodiment is a LFSR (Linear Feedback Shift Register). The result generator 425 in the embodiment is a MISR (Multiple-input Signature Register). The result generator 425 generates the signature result P43 according to testing result P42 and compresses data size for decreasing the data of signature result P43 so as to reduce testing time.

The ways to generate signature result P43 by the result generator 425 are as follows: one way is the result generator 425 generates the signature result P43 according to the testing result by using a checksum algorithm. For example, the testing result P42 outputted by the circuit to be tested 422 includes many sub testing results. The result generator 425 generates many sub-signature results according to those sub-testing results and then sums these sub-signature results together to obtain the signature result P43. The other way is the result generator 425 generates the signature result P43 according to the testing result P42 by performing a polynomial operation.

In the embodiment, the chip to be test 420 uses the BIST technology, thus no need to read the test pattern from a memory. Therefore, in a testing phase, the value of test pattern P41 has no substantial meaning. What is required is to input numbers for the circuit to be tested 422 to operate and to calculate the signature result P43 according to the testing result P42 to verify the chip 420 at last. The pattern generator 424 generates the test pattern P41 by a pseudo-random technique, thus the circuit to be tested 422 executes under a testing status without being limited from the frequency of the memory so as to simplify the working environment. In addition, the method of a chip testing itself could match up the frequency of the chip so as to achieve an at-speed utility.

The chip capable of testing itself and the testing method thereof according to the above embodiment of the invention avoid reading the test pattern from the memory. Therefore, the working frequency is simplified, and the result generator compresses the testing result to simplify the verifying process as well. Compared to millions of circuits in a chip, the BIST technology only adds a few circuits in the chip. It doesn't increase much cost yet decreasing testing time. In addition, the step of inputting a test pattern by a human is omitted, and generating the test pattern by a pseudo-random technique also saves the testing time, thereby reduce time to markets.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A chip capable of testing itself, comprising:
a pattern generator, for generating a test pattern;
a circuit to be tested, for receiving the test pattern and outputting a testing result according to the test pattern; and
a result generator, for generating a signature result according to the test result and verifying the chip by outputting the signature result.

2. The chip according to claim 1, further comprising a first circuit electrically connected to a processor, the first circuit receiving a command from the processor and sending the command to the circuit to be tested so that the circuit to be tested executes the command with the test pattern to generate the testing result.

3. The chip according to claim 1, wherein the testing pattern is generated by a pseudo-random technique.

4. The chip according to claim 1, wherein the pattern generator is a LFSR (Linear Feedback Shift Register).

5. The chip according to claim 1, wherein the result generator is a MISR (Multiple-Input Signature Register).

6. The chip according to claim 1, wherein the result generator generates the signature result according to the testing result by using a checksum algorithm.

7. The chip according to claim 1, wherein the result generator generates the signature result according to the testing result by performing a polynomial operation.

8. A self-testing method for a chip, the chip having a testing mode and electrically connected to a processor, the method being executed under the testing mode, the method comprising the steps of:
generating a test pattern in the chip;
executing a command from the processor according to the test pattern to generate a testing result;
generating a signature result according to the testing result; and
verifying the chip according to the signature result.

9. The method according to claim 8, wherein in the generating a test pattern step, the test pattern is generated by a LFSR (Linear Feedback Shift Register).

10. The method according to claim 8, wherein in the generating a signature step, the signature result is generated by a MISR (Multiple-Input Signature Register).

11. The method according to claim 8, wherein in the generating a signature step, the signature result is generated according to the testing result by using a checksum algorithm.

12. The method according to claim 8, wherein in the generating a signature step, the signature result is generated according to the testing result by performing a polynomial operation.

13. The method according to claim 8, wherein the testing pattern is generated by a pseudo-random technique.

14. A chip capable of testing itself, comprising:
a testing circuit, for generating a test pattern; and
a circuit to be tested, for receiving the test pattern and outputting a testing result;
wherein the testing result is sent to the testing circuit so that the testing circuit generates a signature result according to the testing result and verifies the chip by outputting the signature result.

15. The chip according to claim 14, further comprising a first circuit electrically connected to a processor, the first circuit receiving an command from the processor and sending the command to the circuit to be tested so that the circuit to be tested executes the command with the test pattern to generate the testing result.

16. The chip according to claim 14, wherein the testing circuit comprising:
a pattern generator, for generating the testing pattern by a pseudo-random technique; and
a result generator, for receiving the test result from the testing circuit, and generating a signature according to the test result.

17. The chip according to claim 16, wherein the pattern generator is a LFSR (Linear Feedback Shift Register).

18. The chip according to claim 16, wherein the pattern generator is a MISR (Multiple-Input Signature Register).

19. The chip according to claim 14, wherein the testing circuit generates the signature result according to the testing result by using a checksum algorithm.

20. The chip according to claim 14, wherein the testing circuit generates the signature result according to the testing result by performing a polynomial operation.
